(19) United States
(12) Patent Application Publication
(10) Pub. No.: US 2026/0204951 A1
(43) Pub. Date: Jul. 16, 2026

(54) ENERGY TRANSFER DEVICE

(71) Applicant: Bury Sp.z.o.o., Mielec (PL)

(72) Inventor: Rafal ARCHITEKT, Pacanow (PL)

(73) Assignee: Bury Sp.z.o.o., Mielec (PL)

(21) Appl. No.: 19/419,772

(22) Filed: Dec. 15, 2025

(30) Foreign Application Priority Data
Dec. 16, 2024 (DE) 10 2024 138 065.9

(51) Int. Cl. H02J 50/10; H05K 7/20

(52) U.S. Cl. CPC H02J 50/10; H05K 7/209

(57) ABSTRACT

An energy transfer device for wirelessly transferring energy to a mobile device is described, which comprises a transmitting coil, a ferrite element coupled with the transmitting coil, control electronics connected with the transmitting coil for controlling the transmitting coil, a heat sink, and a thermoelectric element. The thermoelectric element is arranged between the ferrite element and the heat sink.

The invention relates to an energy transfer device for wirelessly transferring energy to a mobile device, wherein the energy transfer device comprises a transmitting coil, control electronics connected to the transmitting coil for controlling the transmitting coil, a heat sink, and a thermoelectric element.

DE 10 2014 117 488 A1 discloses a mobile device holder in which a mobile device is firmly anchored. In the holder body on the rear side of the mobile device, there is a cooling device with a ventilator that blows air from the rear side of the holder to the rear side of the mobile device. The air flowing past the rear side of the mobile device leads to the desired cooling effect. Instead of the ventilator, the cooling device can comprise only a Peltier element, which is arranged on the support surface adjacent to the charging device of the holding device and adjacent to the charging receiving device of the mobile phone, in order to avoid unwanted heating of both charging components.

EP 3 952 055 A1 discloses a wireless energy transfer system, wherein Peltier elements are located between the support surface and the coils. Here, heat is transported from the support surface to the coils and from the coils via a U-shaped heat-conducting sheet to the heat sink on the underside of the housing. In other disclosed embodiments, the Peltier element is placed below the coils or between the coils. In all embodiments, the heat is conducted via a sheet to the heat sink and radiated outwards from the heat sink.

The charging of mobile devices via inductive energy transfer has become increasingly important in recent years. Similar to wired charging, where the mechanical and electrical standard has been established via the Micro-USB or USB-C interface, there is also a transmission standard for inductive energy transfer that allows for the combination of chargers and mobile devices from different manufacturers. In the world of wireless charging, the Qi standard of the WPC (Wireless Power Consortium) has prevailed, which is now supported by all renowned mobile device manufacturers. This standard provides for a defined power transfer of up to 5 watts in the low-power range and up to 15 watts in the medium-power range.

Some mobile device manufacturers have extended this standard for specific phones and are thus able to transfer a power of more than 15 watts. During the charging process, in which electrical energy is converted into magnetic energy in the energy transfer device (also referred to as “transmitter”) and then back into electrical energy in the mobile device to be charged, losses occur in various circuit units of both the transmitter and the mobile device, which are dissipated in the form of heat energy. The higher the power that is transferred, the higher the power loss and thus the heat generation. Another source of heat is the mobile device itself, which typically has a powerful processor clocked in the GHz range. If applications that require a very high processor performance are running on the module device, the heat development is also relatively high, which leads to a further heating of the device.

The electrical energy is typically stored in lithium-ion batteries in the mobile device, whereby charging according to the specification of this battery type should only take place up to a temperature of approx. 45° C. in order to achieve the longest possible service life of the battery and to protect the battery from dangerous operating conditions, which could lead, for example, to a possible fire. This protective functionality is typically implemented in the mobile device itself, which is equipped with a temperature sensor near the battery. Because of the not insignificant consequences of a faulty temperature protection in the mobile device, it is sensible and often even mandatory to install an additional protective function in the charger. Even if charging is carried out at room temperature as the ambient temperature, the battery heats up very quickly to the maximum permissible temperature due to the high losses in the transmitter and in the mobile device. To stop the temperature increase now, either the charging power must be reduced or the charging must be switched off completely, or active cooling must take place. Known cooling methods are to blow or suck ambient air between the mobile device and the support surface. In this process, heat is dissipated from both the mobile device and the transmitter. For this purpose, an air channel must be present between the support surface and the mobile device, which is typically formed by narrow ridges on the support surface in order to thus hold the mobile device at a distance from the support surface.

However, the small distance between the support surface and the mobile device also causes the transmitting and receiving coils to be further apart from each other, which in turn leads to a lower efficiency of the power transfer and thus produces further waste heat.

Another disadvantage arises with a magnetic mount according to the MPP standard. Here, it is essential that the magnets in the support surface and their opposing magnets in the mobile device have a very small distance from each other in order to form a sufficient magnetic force to hold the mobile device. An air gap in between would lead to a significantly lower holding force.

Based on this, it is the object of the present invention to create an improved energy transfer device in which the heat transfer between the mobile device to be charged and the energy transfer device is improved.

The object is achieved by the energy transfer device with the features of claim 1. Advantageous embodiments are described in the dependent claims.

It is proposed that the energy transfer device further comprises a ferrite element coupled with the transmitting coil and the thermoelectric element is arranged between the ferrite element and the heat sink.

In this way, the heat generated in the transmitting coil is dissipated through the inner core material of the coil, i.e., the ferrite element, to a heat sink inside the charger. The heat can then be dissipated from the surface of the heat sink.

For this purpose, the heat sink can have cooling fins, which increase the heated surface area. A fan (i.e., a ventilator) can blow ambient air past the cooling fins, whereby the air absorbs the heat and carries it outwards.

From the core material formed by the at least one ferrite element, which typically consists of a material with good thermal conductivity, heat can also be taken from the support surface for the mobile device, and thus also from the mobile device. Since heat is only conducted from a higher temperature level to a lower one, the temperature at the cooling fins is always somewhat higher than that of the ambient air, and the temperature of the transmitting coil is in turn somewhat higher than that of the core material and the heat sink. This also means that the temperature at the support surface above the transmitting coil is somewhat higher. Due to physical laws, the temperature difference is linear to the heat output that is conducted through the material. Thus, this cooling method is only suitable up to a certain maximum power to cool the mobile device sufficiently.

The overcoming of these physical limits is achieved through the use of a thermoelectric component, in particular a Peltier element. To support the heat dissipation, a thermoelectric element is thus used, which supports the dissipation of heat from the mobile device to the heat sink, on the surface of which an air stream can act for heat dissipation. The thermoelectric component acts between the ferrite element and the heat sink in such a way that the at least one coil can be positioned close to the support surface and the heat from the coil and the support surface is efficiently conducted via the ferrite element and the adjoining thermoelectric component to the heat sink. The thermoelectric element thus serves not just for simple cooling like a ventilator with the air stream it generates, but as a heat-conducting element, through which, with an optimized temperature difference, heat is dissipated from the ferrite element through the thermoelectric element to the heat sink.

The thermoelectric element can preferably be a Peltier element.

A Peltier element consists of differently doped semiconductors that are in contact with each other. Due to the different energy levels of n-and p-doped semiconductors, when current flows, heat energy is absorbed on one side and released on the other. Thus, a temperature difference is created between the two sides of a Peltier element. One also speaks of a cold and a warm side of the element. The structure of the heat-conducting heat sink changes in that a Peltier element is located between the heat sink side, which is in contact with the transmitting coil and the support surface, and the other side of the heat sink with cooling fins, which are streamed by air. The direction of the current through the element is chosen so that the cold side is in contact with the ferrite element and the warm side is connected to the heat sink and its air-streamed cooling fins.

The Peltier element thus has for the main operating direction or nominal polarity a cooler side and a warmer side diametrically opposite the cooler side, wherein the cooler side of the Peltier element adjoins the ferrite element and the warmer side of the Peltier element adjoins the heat sink. However, the polarity can also be reversed, so that the Peltier element can be operated as a cooling element or as a heating element depending on the polarity. The present main operating direction is the polarity in which heat is dissipated via the ferrite element to the heat sink.

The energy transfer device can have a fan, which is configured for air to flow through and/or for air to flow onto the heat sink.

The heat sink can have cooling fins. The cooling fins can, for example, extend radially. They can optionally be inclined in a tangential direction.

The energy transfer device can have at least one temperature sensor, which is connected to the control electronics and is arranged
at the transmitting coil and/or
at the heat sink and/or
in the supply air stream for detecting the ambient temperature and/or
in the exhaust air stream for detecting the heated air dissipated from the heat sink and/or
on a printed circuit board of the control electronics and/or
at a support surface of the electronics device configured for supporting a mobile device to be charged.

The control electronics can be configured to control the fan as a function of the energy transfer power and/or of at least one detected temperature.

The control electronics can be configured to control the thermoelectric element as a function of the energy transfer power and/or of at least one detected temperature.

The control electronics can be configured to control the thermoelectric element, designed as a Peltier element, by means of current direction reversal as a heating element for heating the ferrite element and the support side for the mobile device coupled therewith.

The ferrite element can be a ferrite plate. The ferrite plate can preferably cover the entire at least one transmitting coil, i.e., the transmitting coil arrangement. In this context, any smaller recesses with intermediate spaces, e.g., for passing through supply lines for the transmitting coil, may be present. The ferrite plate preferably protrudes laterally beyond the outer circumference of the transmitting coil.

The invention will be explained in more detail below with reference to an exemplary embodiment with the accompanying drawings. They show:

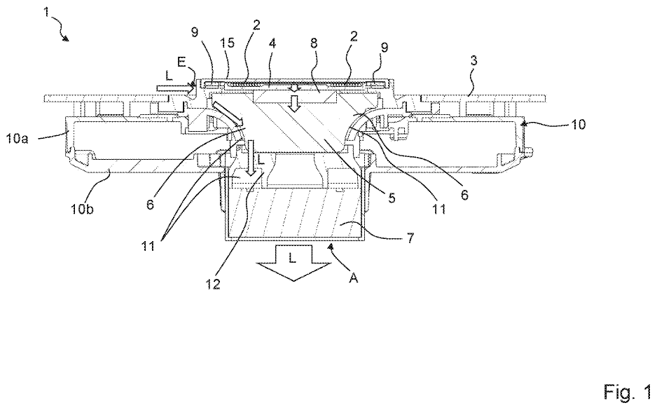

FIG. 1—Side cross-sectional view of the embodiment of the energy transfer device according to the invention with a thermoelectric element between the ferrite element and the heat sink;

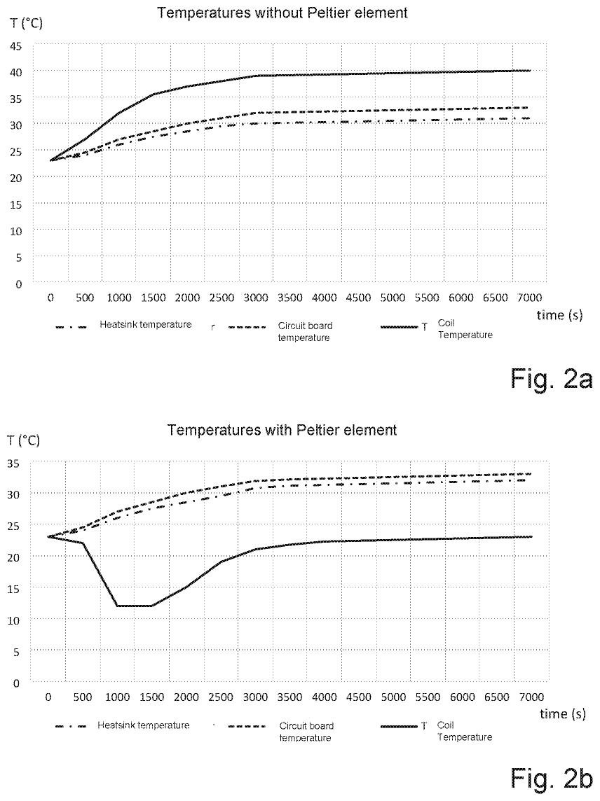

FIG. 2a—Diagram of the temporal temperature profile in a conventional construction;

FIG. 2b—Diagram of the temporal temperature profile in a construction according to the invention with a Peltier element arranged between the ferrite element and the heat sink;

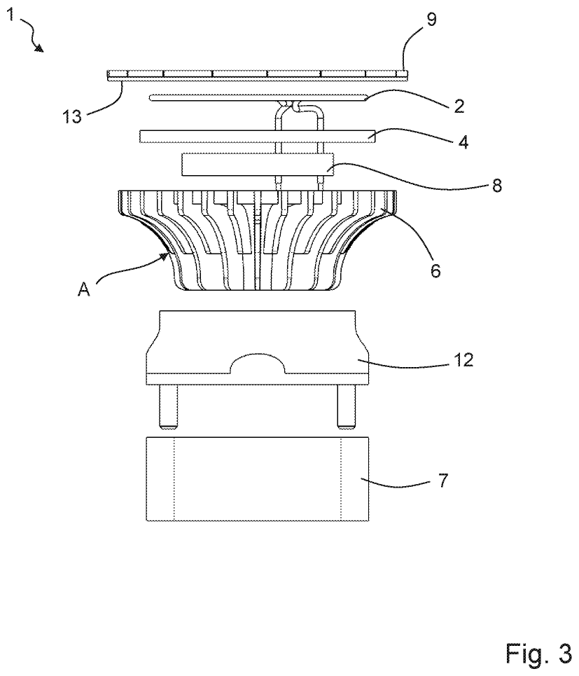

FIG. 3—Exploded view of the energy transfer device from FIG. 1;

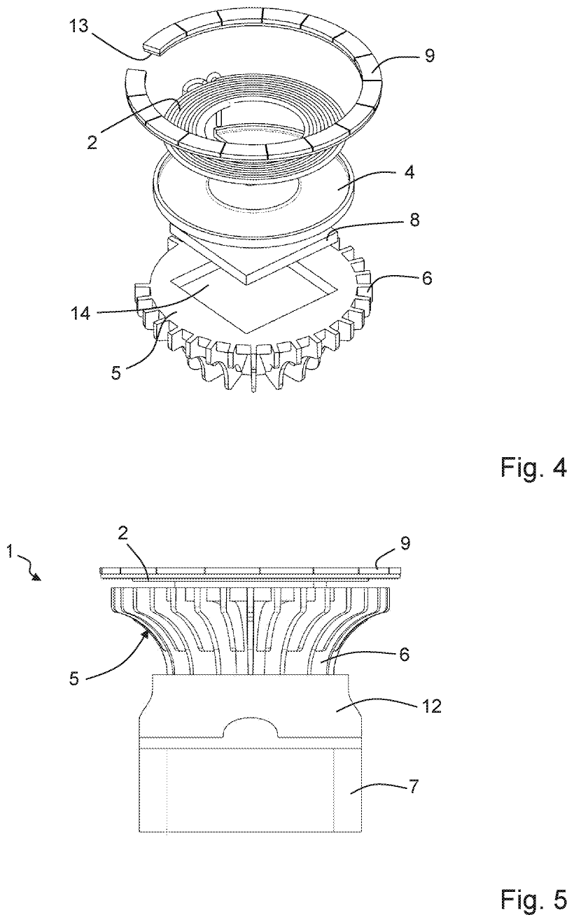

FIG. 4—Perspective exploded view of the heat sink of the energy transfer device from FIG. 3;

FIG. 5—Side view of the energy transfer device from FIG. 3;

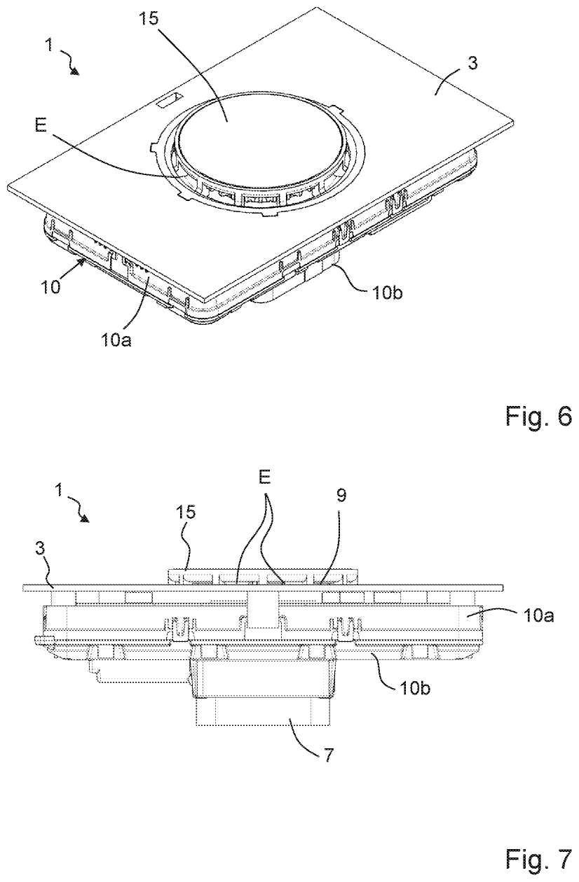

FIG. 6—Perspective view of the energy transfer device;

FIG. 7—Side view of the energy transfer device from FIG. 6.

FIG. 1 shows a side cross-sectional view of an energy transfer device 1.

The energy transfer device 1 has a transmitting coil 2 or transmitting coil unit for creating a wireless charging system and for magnetic fixing of the mobile device to be charged. The transmitting coil 2, which is located directly under the support surface 3 for a mobile device, is recognizable. The support surface 3 is in contact with the mobile device.

Directly below the transmitting coil 2, a ferrite element 4 in the form of a ferrite plate is attached, which guides the magnetic field lines so that the magnetic field forms a magnetic coupling with the receiving coil of the mobile device placed on the support surface 3. Inside the transmitting coil 2 and around the transmitting coil 2, the ferrite plate 4 has an elevation, also for shaping the magnetic field. The ferrite material is also a good heat conductor, whereby the heat from the transmitting coil 2 and from the support surface 3 is conducted to the underside of the ferrite plate 4.

On the underside of the ferrite plate 4, a heat sink 5 with cooling fins 6 is attached, which causes the heat from the ferrite plate 4 to be conducted to the cooling fins 6. Since the heat sink 5 typically consists of a very good heat-conducting material, the temperature difference between the side that is in contact with the ferrite plate 4 and the side with the cooling fins 6 is very small, typically in the range of 1° C.

Underneath the heat sink 5, i.e., on the underside which is facing away from the support surface 3, there is a fan 7, which blows ambient air L past the cooling fins 6 and out again. At the cooling fins 6, the ambient air L absorbs heat from the cooling fins 6 and thus ensures that the cooling fins 6 cool down towards the temperature of the ambient air L.

The heat output that is dissipated from the cooling fins 6 to the air L depends on the temperature difference between the cooling fins 6 and the air L and on the air flow speed. The higher the temperature difference, the greater the transferred heat output, and the higher the air flow speed, the greater the heat dissipation as well. For a certain flow speed and a certain heat output dissipation, an equilibrium is established, which results in a certain temperature difference.

Instead of or in addition to the direct connection, a thermoelectric element 8 is arranged between the ferrite plate 4 and the heat sink 5. The direction of current through this thermoelectric element 8 is chosen so that the cold side is in contact with the ferrite plate 4. The warm side of the thermoelectric element 8 is connected to the heat sink 5, which has the cooling fins.

It can be seen in FIG. 1 that the thermoelectric element 8 is located under the ferrite element 4, which is designed as a ferrite plate, and can be configured as a Peltier element, for example.

As an example of the direct coupling between ferrite element 4 and heat sink 5, the temperature of the ambient air is assumed to be 23° C. and the temperature of the cooling fins 6 at the heat dissipation power considered here is 10° C. higher, i.e., 33° C. At the contact surface to the ferrite plate 4, the temperature is 34° C. and on the support surface 3, which is typically made of plastic, it is, for example, 39° C. The underside of the mobile device would then have a temperature of 42° C. and the battery of the mobile device, which is located near the underside, 44° C. This is very close to the maximum charging temperature of 45° C. A further increase in charging power is not possible, as otherwise the battery temperature would rise above 45° C. and the safety electronics in the mobile device would switch off the charging.

If now for the arrangement of the thermoelectric element 8 between ferrite element 4 and heat sink 5 the same heat output is assumed as in the example of direct coupling without a Peltier element, then the ambient air temperature is again 23° C. and the temperature of the cooling fins 6 is also 33° C. The other side of the heat sink 5 at the contact surface to the Peltier element has a temperature of 34° C. The current intensity through the thermoelectric element 8 is chosen such that a difference of 10° C. is established between the warm and cold side. Thus, the cold side of the Peltier element 8 and also the ferrite plate 4 have a temperature of 24° C. and the support surface is 29° C. warm, the underside of the mobile device is 32° C., and the battery temperature is 34° C. In this case, the charging power can be further increased without the battery of the mobile device to be charged reaching a critical temperature range and the charging having to be switched off.

Around the transmitting coil 2, a ring-shaped arrangement of individual magnets 9 can optionally be located, which form a force connection with the opposing magnet in the mobile device and hold the mobile device in a fixed, predefined position.

It can be seen that the components described above can be installed in a housing 10, which can be multi-part. In the housing 10, at least one air channel 11 is formed with an inlet E on the upper side in the area of the support surface 3 and an outlet A at the fan 7 (i.e., the ventilator), whereby the slots between adjacent cooling fins 6 form a part of the air channel 11.

The housing 10 can have an upper housing shell 10a and a lower housing shell 10b.

Between the heat sink 5 and the fan 7, an air funnel 12 can be arranged, which collects the air L from the vertical channels 11 distributed around the circumference of the heat sink 5 between the cooling fins 6 and guides it to the fan 7.

In FIGS. 2a and 2b, the temperature profile T in degrees Celsius is shown over time t in seconds for a charging power of 18 watts.

FIG. 2 a shows the temporal temperature profile T in a conventional construction with a heat sink 5, which is directly connected to the ferrite plate 4 by means of thermal paste. The temperature at the cooling fins 6 of the heat sink 5 increases at an ambient air temperature of 23° C. to 31° C. and the transmitting coil temperature increases to 40° C. These values refer to an average air flow L initiated by the fan 7. Since the transmitting coil 2 is located directly below the support surface 3 for the mobile device, the coil temperature is a very good indicator also for the surface temperature of the support surface 3, i.e., the surface temperature is approx. 40° C. Since the battery temperature is a few ° C. higher due to the losses in the battery and in the mobile device, the charging would now switch off.

FIG. 2b shows the temporal temperature profile in the construction according to the invention, in which a Peltier element 8 is located between the ferrite plate 4 and the heat sink 5. The heat sink 5 also has cooling fins 6, past which a fan 7 blows ambient air L. In the static state, i.e., after some time of electromagnetic charging with 18 W, the cooling fin temperature has increased to 32° C. The slightly higher temperature compared to the case without Peltier cooling on the cooling fins is explained by the fact that, in addition to the waste heat from the wireless charging, the losses from the Peltier element 8 must also be dissipated, which leads to an increase in the heat sink temperature. The temperature of the transmitting coil 2, which is also an indication of the temperature of the ferrite plate 4 and the support surface 3, is now 23° C. This has the consequence that the significantly lower temperature of the support surface 3 is transferred to the mobile device and its battery, thus leaving more room for a longer charge and also for charging with higher power.

FIG. 3 shows an exploded view of an energy transfer device 1 according to the invention.

The magnetic ring formed from magnets 9 is recognizable, which has a larger diameter than the at least one transmitting coil 2 accommodated in the magnetic ring. The magnets 9 can be mounted on a ring-shaped carrier 13.

Below the transmitting coil 2 is a ferrite element 4 in the form of a ferrite plate, which completely covers the underside of the transmitting coil 2 and preferably protrudes beyond the sides of the transmitting coil 2. The ferrite plate 4 can be circular, just like the transmitting coil 12. Other contours are, however, equally conceivable.

The underside of the ferrite plate 4 opposite the transmitting coil 2 is connected to the thermoelectric element 8, which is preferably designed as a Peltier element.

The supply lines of the transmitting coil 2 can be guided through the ferrite plate 4 in the direction of the heat sink 5. They can pass by the thermoelectric element 8 between the cooling fins 6 of the heat sink 5 to a printed circuit board, which can be located in the area of the fan 7, the air funnel 12, or the narrow side of the conically tapering heat sink 5 adjacent to the air funnel 12.

FIG. 4 shows the energy transfer device 1 from FIG. 3 in a perspective view and FIG. 5 in a side view.

It can be seen that the heat sink 5 has a recess 14, for example, a rectangular recess as shown, into which the thermoelectric element 8 (e.g., Peltier element) is inserted. The contour of the recess 14 can, however, also be chosen differently, e.g., circular.

Any unevenness on the surface of the Peltier element 8 or on the surface of the heat sink 5, which could impair heat transfer, can be bridged with thermal paste. On the heat sink side opposite the rectangular recess, a number of knobs can be located, which increase the radiation surface of the heat sink 5 and thus the contact area for the air flow. Through recesses in a ring surrounding the knobs, the air reaches optionally slightly tangentially inclined further cooling fins 6. The inclination serves to also increase the air contact surface, and thus also the efficiency of the heat dissipation. Other forms of cooling fins 6 are, however, equally conceivable.

Furthermore, at least one temperature sensor can be present, which can be located on the heat sink 5 and/or on a cover serving as a support and/or in the vicinity of the transmitting coil 2 and/or on the printed circuit board and/or in the air stream L. With the help of these temperature sensors, the thermal state of the charging system can be detected. These temperatures are connected to the control electronics. The control of the transmitting coils 2 and the thermoelectric element 8 as well as the fan 7 is then carried out with the help of the detected temperature at the at least one measurement position.

The control electronics can be implemented with a programmed microprocessor or microcontroller, an FPGA, an ASIC, and the like. Thus, the control electronics of the charging system can realize the control of the cooling system in addition to the control of the wireless charging. A separate microcontroller for the cooling system can also be present. The cooling system can be controlled by changing the air flow rate or speed, in particular by the voltage at the fan, and/or by the electric current through the Peltier element. The control can be designed from the point of view that the air flow rate is minimized just enough so that the mobile device remains sufficiently cool. This has the consequence that the noise pollution from the fan is as low as possible.

The control can be designed from the point of view that the current through the Peltier element 8 is minimized just enough so that the mobile device remains sufficiently cool. This is advantageous in order to keep the power consumption of the system as low as possible. This is particularly advantageous for electric vehicles that are powered by a drive battery.

The control can also combine both previously described aspects.

The control can also be designed to reverse the current through the Peltier element 8 and to heat the transmitting coil 2 and the support surface 3 for the case that the vehicle temperature after a parking process is below the minimum temperature required for battery charging.

FIG. 6 shows a perspective view of the energy transfer device 1 and FIG. 7 shows a side view of the energy transfer device 1 from FIG. 6.

The top side has a support surface 15 made of plastic, which covers the arrangement of the transmitting coil 2 and magnets 9. The mobile device rests on this surface and is held by the magnetic force. The support surface 15 protrudes from the upper housing shell 10a of the housing 10.

It is recognizable that the cover 3 has slots as an inlet E for the channel 11 in the transition to the circularly raised support surface 15, in order to suck in ambient air L in the area of the mobile device to be charged for heat dissipation or, in reverse operation, to blow out ambient air L for cooling or heating from the then outlet E towards

A shielding surface made of flexible PCB material with a conductive structure applied to it can be attached inside the support surface 15 in order to shield the emissions of the electric field.

On the underside of the upper housing shell 10a, the transmitting coil 2 is arranged with the ferrite plate 4. Below this is the thermoelectric element 8, in this embodiment a Peltier element. The top side of the thermoelectric element 8 is contacted with the ferrite plate 4 of the transmitting coil 2 and the underside of the thermoelectric element 8 with the heat sink 5 arranged below it. Below that is the air funnel 12, which collects the air L flowing past the cooling fins 6 of the heat sink 4 from above in the air funnel 12 and guides it to the fan 7 arranged below.

In the housing 10, a printed circuit board with the entire control electronics for controlling the wireless energy transfer can be installed. In this case, a plug connector to the vehicle wiring harness can be arranged on the housing 10 and connected to the control electronics. The printed circuit board can have a circular recess in the middle, into which the air funnel 12 can engage from above and the fan 7 from below. At the very bottom, the lower housing shell can be seen, which accommodates the fan 7, which sucks in the ambient air L, guided from the inlet E through the channels 11 and the air funnel 12, through a central hole as an outlet A, or in reverse operation, sucks in the ambient air L through the central hole (outlet A) and guides it via the air funnel 12 to the heat sink 5.

### REFERENCE SIGNS LIST

1 Energy transfer device
2 Transmitting coil
3 Cover
4 Ferrite element/Ferrite plate
5 Heat sink
6 Cooling fins
7 Fan
8 Thermoelectric element/Peltier element
9 Magnet
10 Housing
10a Upper housing shell
10b Lower housing shell
11 Channel
12 Air funnel
13 Carrier
14 Recess
15 Support surface
A Outlet
E Inlet
L Ambient air

1. An energy transfer device for wirelessly transferring energy to a mobile device, wherein the energy transfer device comprises a transmitting coil, a ferrite element coupled with the transmitting coil, control electronics connected with the transmitting coil for controlling the transmitting coil, a heat sink, and a thermoelectric element, characterized in that the thermoelectric element is arranged between the ferrite element and the heat sink.

2. The energy transfer device according to claim 1, characterized in that the thermoelectric element is a Peltier element.

3. The energy transfer device according to claim 2, characterized in that the Peltier element comprises a cooler side and a warmer side diametrically opposite the cooler side, wherein the cooler side of the Peltier element adjoins the ferrite element and the warmer side of the Peltier element adjoins the heat sink.

4. The energy transfer device according to claim 1, characterized in that the energy transfer device comprises a fan which is configured for air to flow through and/or for air to flow onto the heat sink.

5. The energy transfer device according to claim 1, characterized in that the heat sink comprises cooling fins.

6. The energy transfer device according to claim 5, characterized in that the cooling fins extend radially and are inclined in a tangential direction.

7. The energy transfer device according to claim 1, characterized in that the energy transfer device comprises at least one temperature sensor which is connected to the control electronics and is arranged
at the transmitting coil and/or
at the heat sink and/or
in the supply air stream for detecting the ambient temperature and/or
in the exhaust air stream for detecting the heated air dissipated from the heat sink and/or
on a printed circuit board of the control electronics and/or
at a support surface of the electronics device configured for supporting a mobile device to be charged.

8. The energy transfer device according to claim 1, characterized in that the control electronics is configured to control the fan as a function of the energy transfer power and/or of at least one detected temperature.

9. The energy transfer device according to claim 1, characterized in that the control electronics is configured to control the thermoelectric element as a function of the energy transfer power and/or of at least one detected temperature.

10. The energy transfer device according to claim 1, characterized in that the control electronics is configured to control the thermoelectric element, which is designed as a Peltier element, by means of current direction reversal as a heating element for heating the ferrite element and the support side for the mobile device coupled therewith.

11. The energy transfer device according to claim 1, characterized in that the ferrite element is a ferrite plate.
